(19) United States
(12) Patent Application Publication
(10) Pub. No.: US 2026/0150743 A1
(43) Pub. Date: May 28, 2026

(54) MOLDING APPARATUS, PLANARIZATION APPARATUS, MOLDING METHOD, AND ARTICLE MANUFACTURING METHOD

(71) Applicant: CANON KABUSHIKI KAISHA, Tokyo (JP)

(72) Inventors: MASAHIRO SHIMIZU, Tokyo (JP); SENTARO AIHARA, Tochigi (JP)

(21) Appl. No.: 19/390,067

(22) Filed: Nov. 14, 2025

(30) Foreign Application Priority Data
Nov. 28, 2024 (JP) 2024-207052

(51) Int. Cl. H01L 23/00

(52) U.S. Cl. CPC H10W 72/0113; H10W 72/013; H10W 72/01351

(57) ABSTRACT

A molding apparatus includes an adhesive layer forming unit that forms an adhesive layer on a substrate, a supply unit that supplies a droplet of a molding material to the substrate, an image acquisition unit that acquires an image of the droplet of the molding material supplied on the specific substrate on which the adhesive layer is formed, and a control unit that determines a forming condition for forming an adhesive layer by the adhesive layer forming unit based on the image.

### BACKGROUND

### Field of the Technology

The present disclosure relates to a molding apparatus, a planarization apparatus, a molding method, and a manufacturing method for an article.

### Description of the Related Art

As demands for miniaturization of semiconductor devices continue to grow, in addition to conventional photolithography techniques, a technique referred to as an imprinting technique is attracting attention as a microfabrication technique in which a photocurable composition applied on a substrate is molded using a mold and cured by being irradiated with light, and the mold is separated from the cured composition to form a pattern on the substrate.

A technique for planarizing a composition on a substrate using an imprinting technique is described (see Japanese Unexamined Patent Application Publication No. 2011-529626). Similar to an imprint technique, the planarization technique is to form a flat surface on a substrate by applying a photocurable composition to the substrate and curing the composition in a state where a mold having a flat surface is brought into contact with droplets of the applied composition.

In the above-described imprint technique and planarization technique, a technique has been described in which a shape of a droplet of an applied molding material (for example, a photocurable composition) is imaged using an image capturing apparatus, it is determined whether a diameter of the droplet satisfies a predetermined standard based on acquired image information, and the determination result is used to determine whether imprinting can be performed (see Japanese Patent No. 6853865).

In addition, a technique related to a film forming apparatus has been described in which a film material is applied to a substrate based on predetermined pattern data to form an evaluation pattern, the evaluation pattern is imaged using an image capturing apparatus, and quality of a surface state of the substrate is determined based on the captured image (see Japanese Patent Laid-Open No. 2018-030046).

### SUMMARY

The present disclosure is directed to the provision of a technique advantageous in precisely molding a molding material on a substrate.

According to an aspect of the present disclosure, a molding apparatus includes an adhesive layer forming unit configured to form an adhesive layer on a substrate, a supply unit configured to supply a droplet of a molding material to the substrate, an image acquisition unit configured to acquire an image of the droplet of the molding material supplied on a specific substrate on which the adhesive layer is formed, and a control unit configured to determine a forming condition for forming an adhesive layer on a substrate different from the specific substrate by the adhesive layer forming unit based on the image.

Further objects or other aspects of the present disclosure will become apparent from the following description of embodiments with reference to the attached drawings.

Features of the present disclosure will become apparent from the following description of embodiments with reference to the attached drawings. The following description of embodiments is described by way of example.

### BRIEF DESCRIPTION OF THE DRAWINGS

FIG. 1 illustrates a configuration of a planarization apparatus that is one form of a molding apparatus according to an embodiment of the present disclosure.

FIG. 2 illustrates a configuration of a control unit of the planarization apparatus according to the embodiment.

FIG. 3 illustrates a configuration of an adhesive layer forming unit of the planarization apparatus according to the embodiment.

FIG. 4 illustrates a flow for conveying a substrate in the planarization apparatus according to the embodiment.

FIG. 5 is a flowchart illustrating a processing flow according to the embodiment.

FIGS. 6A to 6E illustrate a method for detecting an abnormal droplet from an image of droplet arrangement of a planarization material according to the embodiment.

FIGS. 7A to 7C illustrate a method for extracting a droplet area from an image of droplet arrangement of a planarization material according to the embodiment.

FIGS. 8A and 8B illustrate a method for measuring a size of a droplet from an image of droplet arrangement of a planarization material according to the embodiment.

FIGS. 9A and 9B illustrate a method for calculating a contact angle of a planarization material from an image of droplet arrangement of the planarization material according to the embodiment.

FIGS. 10A and 10B illustrate a method for changing a supply condition based on a calculated contact angle according to the embodiment.

FIGS. 11A and 11B illustrate configurations of the planarization apparatus and an adhesive layer forming apparatus according to the embodiment.

### DESCRIPTION OF THE EMBODIMENTS

Generally, various compositions are applied to a surface of a substrate and used in a manufacturing process of a semiconductor device. The manufacturing process includes a process in which an adhesive material is applied to form an adhesive layer that improves adhesion between a composition to be applied later and the substrate.

It is known that an applied state of the adhesive material affects subsequent formation of the composition, and for example, there is a possibility that planarization performance may be deteriorated in planarization processing.

Japanese Patent Laid-Open No. 2018-030046 describes adjusting a composition to be applied and controlling processing based on an analysis result of a captured image, but there is a case where planarization performance cannot be sufficiently improved depending on a state of an adhesive layer, which is an underlayer.

Embodiments of the present disclosure will be described in detail below with reference to the attached drawings. It is noted that the following embodiments are not meant to limit the scope of the present disclosure as encompassed by the appended claims. A plurality of features is described in the embodiments, but not all of these features are essential to the present disclosure, and the plurality of features may be arbitrarily combined.

### First Embodiment

The present embodiment relates to a planarization apparatus that forms a planarization layer on a substrate using an imprint technique. The planarization apparatus is an apparatus that planarizes a surface of a composition by bringing a mold having a flat surface into contact with the composition on a substrate. Processing performed by the planarization apparatus may sometimes be referred to as planarization processing.

The planarization apparatus of the first embodiment according to the present disclosure will now be described. The planarization apparatus is an apparatus that molds a composition on a substrate using a mold and planarizes the substrate. The planarization apparatus can be adopted to a planarization process that is a manufacturing process of a semiconductor device, a magnetic storage medium, and the like. A process for bringing a mold into contact with a composition on a substrate, curing the composition, and separating the mold from the cured composition to mold the composition may sometimes be referred to as imprinting. A mold used in the planarization apparatus has a flat surface as a molding surface (contact surface) that contacts a composition on a substrate to mold the composition and may sometimes be referred to as a superstrate or a plane template. Hereinbelow, a mold having a flat surface may sometimes be referred to as “superstrate”.

An underlying pattern on a substrate has an uneven height difference caused by a pattern formed in a previous process, and if the height difference is large, the underlying pattern may fall outside a depth of focus (DOF) of an exposure apparatus used in a subsequent process. Conventionally, methods for forming a planarization layer, such as spin on carbon (SOC) and chemical mechanical polishing (CMP), are used as methods for smoothing an underlying pattern on a substrate. However, the height difference of unevenness of the underlayer due to multilayering tends to increase year by year, and there is an issue that the conventional technology cannot achieve sufficient planarization performance. To address this issue, the planarization apparatus according to the present embodiment uses a superstrate having a flat surface to planarize a composition on a substrate. Specifically, the composition is cured in a state where the flat surface of the superstrate contacts with the composition supplied on the substrate, and the superstrate is separated from the cured composition. Accordingly, a planarization film (planarization layer) made of the cured composition can be formed on the substrate.

A composition to be used is a curable composition (sometimes referred to as an uncured resin) that is cured if a curing energy is applied. The curing energy to be used may be an electromagnetic wave, heat, or the like. Electromagnetic waves include, for example, light of which a wavelength is selected from a range of 10 nm or more and 1 mm or less, specifically infrared light, visible light, ultraviolet light, and the like. A curable composition may be a composition that is cured by irradiation with light or by heating. Among these, a photocurable composition that is cured by irradiation with light contains at least a polymerizable compound and a photopolymerization initiator and may contain a non-polymerizable compound or a solvent as necessary. A non-polymerizable compound is at least one type selected from a group including a sensitizer, a hydrogen donor, an internal mold release agent, a surfactant, an antioxidant, a polymer component, and the like. The composition can be arranged on the substrate in a droplet form or in an island or film form, which is formed by a plurality of droplets connected together, by a composition supply apparatus (a supply unit 20 described below). For example, the composition dropped on the substrate may be arranged thereon as a hemispherical droplet with a minute volume and a diameter of about 10 μm to 20 μm. A viscosity of the composition (viscosity at 25° C.) can be, for example, 1 mPa's or more and 100 mPa's or less.

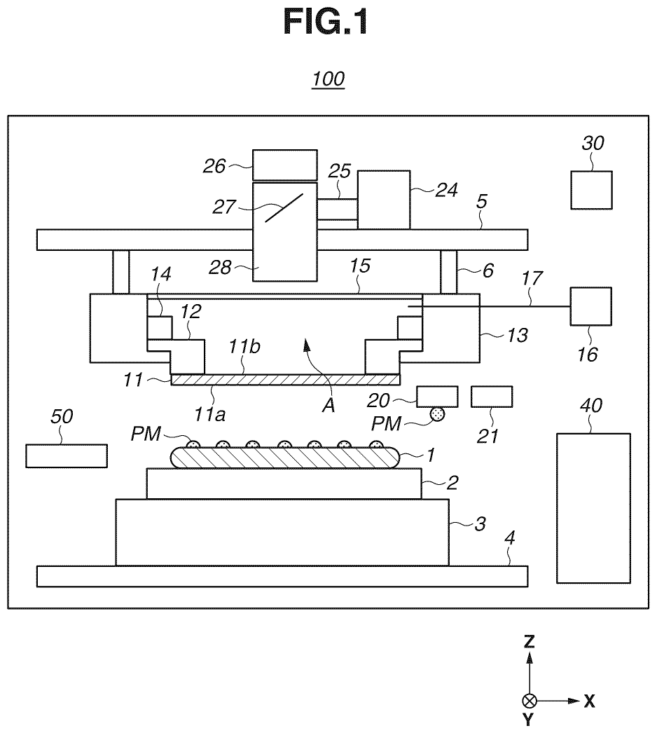

FIG. 1 is a schematic diagram illustrating an example of a configuration of a planarization apparatus 100 that is a molding apparatus according to the present embodiment.

In FIG. 1, a substrate 1 is conveyed by a substrate conveyance unit 50 that includes a conveyance hand and the like and is held by a substrate chuck 2 that is a substrate holding unit. A substrate stage 3 is configured to be movable on a base surface plate 4 and drives the substrate chuck 2 to drive the substrate 1 in X-axis and Y-axis directions to position the substrate 1 held by the substrate chuck 2 at a predetermined position. A material of the substrate 1 can be, for example, glass, ceramics, metal, semiconductor, resin, or the like.

If necessary, a member made of a material different from that of the substrate 1 may be provided on a surface of the substrate 1.

The substrate 1 includes, for example, a silicon wafer, a compound semiconductor wafer, and quartz glass. The substrate 1 has an uneven structure caused by a pattern formed in a previous process, and the planarization apparatus 100 is used to form a planarization film that covers the uneven structure on the substrate 1.

As described below, an adhesive layer is formed on the substrate 1 prior to planarization processing to improve adhesion between the substrate 1 and the composition. The adhesive layer is formed by applying an adhesive material by an adhesive layer forming unit 40. After the adhesive layer is formed on the substrate 1 by the adhesive layer forming unit 40, the substrate 1 is conveyed by the substrate conveyance unit 50 onto the substrate chuck 2 and is subjected to planarization processing.

A superstrate 11 (mold) can be made of a light-transmitting material (quartz glass or the like). The superstrate 11 has, for example, a circular outer shape if viewed from a +Z-axis direction. A molding surface (first surface) that contacts with a composition PM on the substrate 1 to mold the composition PM is a flat surface 11a. If the flat surface 11a of the superstrate 11 contacts with the composition PM on the substrate 1, the superstrate 11 can be deformed and conform to a surface shape of the substrate 1 (an uneven shape viewed from the X-axis direction or the Y-axis direction) due to a surface tension of the composition PM. An outer diameter of the superstrate 11 is, for example, the same as an outer diameter of the substrate 1. The superstrate 11 is conveyed into the planarization apparatus 100 by a mold conveyance unit (not illustrated) and held by a holding member 12 (a mold holding unit or a mold chuck). The holding member 12 holds the superstrate 11 by contacting with and attracting an outer peripheral portion of a back surface 11b (a surface (second surface) on the opposite side of the flat surface 11a) of the superstrate 11. The holding member 12 can hold the superstrate 11 by, for example, vacuum suctioning the outer peripheral portion of the superstrate 11.

The holding member 12 is supported by a head 13. The head 13 can include a drive mechanism that drives the holding member 12 to drive the superstrate 11. For example, the head 13 drives the superstrate 11 in a Z-axis direction to bring the superstrate 11 into contact with the composition PM on the substrate 1 and to separate the superstrate 11 from the cured composition PM. The head 13 may have a function of correcting a tilt of the superstrate 11. The drive mechanism in the head 13 can be configured with, for example, an actuator such as a linear motor, an air cylinder, a voice coil motor, or the like. The head 13 is fixed to a guide bar 6 that is suspended by a bridge structure 5. The bridge structure 5 is supported by a support pillar (not illustrated) fixed to the base surface plate 4.

The holding member 12 is supported by the head 13 to be able to tilt with respect to the head 13 based on a shape of the back surface 11b in a state where a holding surface (a surface that holds the superstrate 11) of the holding member 12 is in contact with the back surface 11b of the superstrate 11. In other words, the holding member 12 has flexibility that enables it to tilt according to the shape of the superstrate 11. For example, in a case where an external force is applied to the superstrate 11 held by the holding member 12, and the entire superstrate 11 is bent and deformed into a downward convex shape, the holding member 12 tilts so that the holding surface faces outward. Accordingly, the shape of the superstrate 11 can be maintained as a quadratic curved surface that is downwardly convex. In a case where the entire superstrate 11 is bent and deformed into an upward convex shape, the holding member 12 tilts so that the holding surface faces inward. Accordingly, the shape of the superstrate 11 can be maintained as a quadratic curved surface that is upwardly convex.

The head 13 is provided with a force detection unit 14 (second detection unit) that detects a pressing force of the superstrate 11 by the holding member 12. The force detection unit 14 may detect an external force transmitted to the holding member 12 via the superstrate 11. The force detection unit 14 can be, for example, a strain gauge type load sensor or a load sensor (load cell) that detects a force from a current value applied to the drive mechanism (actuator) of the head 13. In FIG. 1, the force detection unit 14 is illustrated as a separate configuration from the head 13 and the holding member 12, but it may be included in the head 13 or the holding member 12.

The head 13 is provided with a flat optical element 15 made of a light-transmitting member such as quartz glass or the like. The flat optical element 15 is attached to the head 13 so that a spatial domain A, which is a closed space, is formed between the superstrate 11 and the flat optical element 15.

The flat optical element 15 functions as a sealing member that forms the spatial domain A as a closed space. An internal pressure of the spatial domain A can be adjusted (controlled) by a pressure adjustment unit 16 via a pipe 17. For example, the pressure adjustment unit 16 adjusts the internal pressure of the spatial domain A to be higher than atmospheric pressure, thereby deforming the superstrate 11 into the downward convex shape and gradually bringing the superstrate 11 into contact with the composition PM on the substrate 1 from its central portion. Accordingly, it is possible to reduce trapping of an air bubble between the superstrate 11 and the substrate 1.

In planarization processing, a curing unit 24 irradiates a liquid film of the composition PM formed between the superstrate 11 and the substrate 1 with light (for example, ultraviolet light (UV)) to cure the composition PM. The curing unit 24 according to the present embodiment includes a light source including a UV lamp or a UV light-emitting diode (UVLED). The light emitted from the curing unit 24 passes through an optical path tube 25 including a collimator lens (not illustrated), is reflected by a mirror 27, is emitted from an opening portion 28, and is radiated onto the composition PM on the substrate 1 via the superstrate 11.

In a case where the shape and size of the superstrate 11 and the substrate 1 are the same, in a state where the superstrate 11 is held by the holding member 12, the holding member 12 blocks light irradiation to an area of the surface of the substrate 1 facing the holding member 12. In other words, the composition PM in the area of the surface of the substrate 1 may not cure sufficiently. Thus, in the planarization apparatus 100 according to the present embodiment, the superstrate 11 is brought into contact with the composition PM on the substrate 1 to form the liquid film of the composition PM between the superstrate 11 and the substrate 1, and then the superstrate 11 is released from holding by the holding member 12. Then, the head 13 raises the holding member 12 to isolate (separate) the holding member 12 from the superstrate 11, and the curing unit 24 irradiates the liquid film of the composition PM between the superstrate 11 and the substrate 1 with light in this state. Accordingly, the light from the curing unit 24 is prevented from being blocked by the holding member 12, so that an area irradiated with light can be expanded on the substrate 1, and the composition PM can be cured over the entire area of the substrate 1. According to the present embodiment, the example is described in which the curing unit 24 emits curing light as a curing unit, but the curing unit may be a unit other than a light source.

A spread camera 26 observes a contact state between the superstrate 11 and the composition PM on the substrate 1, i.e., a state of the liquid film of the composition PM formed between the superstrate 11 and the substrate 1. The spread camera 26 includes, for example, a wide-angle lens and has a wide field of view (angle of view) that can observe the entire area of the substrate 1 without the camera's field of view being limited by a size of the opening portion 28. In a case where the spread camera 26 detects the contact state between the superstrate 11 and the composition PM on the substrate 1, the mirror 27 can be retracted from the field of view of the spread camera 26. The present disclosure is not limited to this, and the mirror 27 may be configured with a half mirror that reflects light from the curing unit 24 and transmits light to the spread camera 26.

The supply unit 20 supplies the composition PM onto the substrate 1. The supply unit 20 according to the present embodiment is configured with a dispenser including an ejection port (nozzle) that ejects the composition PM (an uncured resin) onto the substrate 1. For example, the supply unit 20 adopts a piezo jet method, a micro solenoid method, or the like and is configured to eject the composition PM as a plurality of droplets each having a minute volume of about 1 picoliter (pL). In a state where the substrate 1 is moved below the supply unit 20 in the XY direction by the substrate stage 3, the supply unit 20 ejects the composition PM as a plurality of droplets and thus can discretely supply the plurality of droplets of the composition PM over the entire area of the substrate 1.

An image acquisition unit 21 captures an image of droplets of the composition PM on the substrate 1 ejected from the supply unit 20 and acquires a droplet arrangement image. For example, an image capturing unit is used that includes a lens with a narrower angle of view than that of the spread camera 26 and can capture an image more precisely despite a narrow field of view. The image acquisition unit 21 is typically configured separately from the spread camera 26 in order to observe a droplet, but the spread camera 26 may be substituted for the image acquisition unit 21.

A control unit 30 is connected to each unit in the planarization apparatus 100 and controls planarization processing by controlling each unit in the planarization apparatus 100. Planarization processing is processing in which the flat surface 11a of the superstrate 11 contacts with the composition PM on the substrate 1 and conforms to the surface shape of the substrate 1 to planarize the composition PM on the substrate 1. The control unit 30 is an information processing apparatus that can be configured with, for example, a programmable logic device (PLD) such as a field programmable gate array (FPGA) or the like, an application specific integrated circuit (ASIC), a computer with an embedded program, or a combination of all or part of these components. The control unit 30 can also be configured with a plurality of information processing apparatuses. The control unit 30 may be configured in a common housing together with the other components of the planarization apparatus 100 or may be configured in a housing separate from the other components of the planarization apparatus 100.

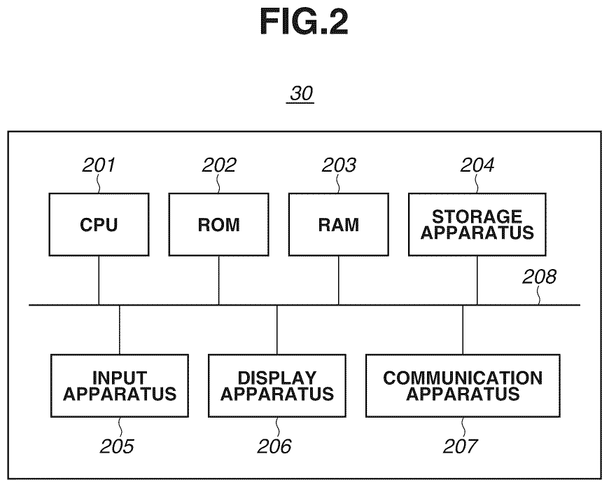

FIG. 2 illustrates a configuration of the control unit 30. The control unit 30 can be realized by a computer (information processing apparatus). In FIG. 2, a central processing unit (CPU) 201 (processing unit) executes an operating system (OS) and various application programs. The CPU 201 is not limited to a CPU, but may be a processor or a circuit such as a micro processing unit (MPU), a graphics processing unit (GPU), an ASIC, or the like. The CPU 201 may be any combination of these processors or circuits.

A read-only memory (ROM) 202 is a memory that stores a program executed by the CPU 201 and fixed data among calculation parameters. A random access memory (RAM) 203 is a memory that provides a work area for the CPU 201 and a temporary storage area for data. The ROM 202 and the RAM 203 are connected to the CPU 201 via a bus 208. An input apparatus 205 (input unit) includes a mouse, a keyboard, and the like. A display apparatus 206 (display unit) includes a cathode ray tube (CRT), a liquid crystal display, or the like. The input apparatus 205 and the display apparatus 206 may be an integrated apparatus such as a touch panel or the like.

The input apparatus 205 and the display apparatus 206 may be configured as apparatuses separate from the computer. A storage apparatus 204 is a hard disk device, a compact disk (CD), a digital versatile disk (DVD), a memory card, or the like and stores various programs, various kinds of data, and the like. The input apparatus 205, the display apparatus 206, and the storage apparatus 204 are each connected to the bus 208 via an interface (not illustrated). A communication apparatus 207 that connects to a network to perform communication is also connected to the bus 208. The communication apparatus 207 is used in a case where, for example, it is connected to a local area network (LAN) to perform data communication using a communication protocol such as Transmission Control Protocol/Internet Protocol (TCP/IP) or the like and to perform mutual communication with another communication apparatus.

The communication apparatus 207 functions as a transmission unit and reception unit of data and, for example, receives data such as operation information or the like from a transmission unit (not illustrated) in the planarization apparatus 100 and stores it in the storage apparatus 204.

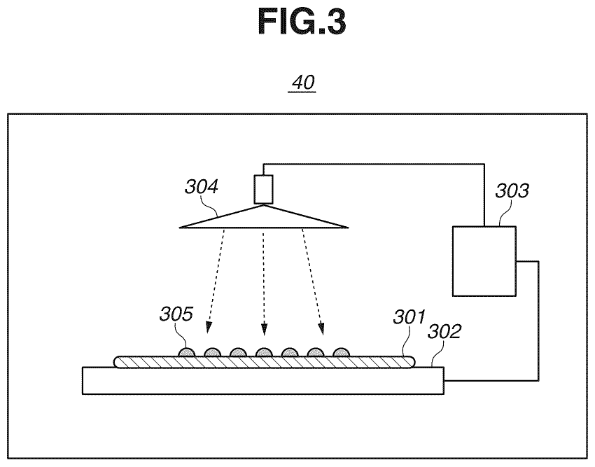

FIG. 3 illustrates a configuration of the adhesive layer forming unit 40. The adhesive layer forming unit 40 according to the present embodiment includes an ejection port 304 that applies an adhesive material 305 onto a substrate 301, a temperature adjustment mechanism 302 that adjusts a temperature of the substrate 301, and a control unit 303 that adjusts and controls an amount and an ejection position of an adhesive material to be applied. A forming method and a configuration of the forming unit are not limited to the above-described method and configuration. A general film forming method such as a vapor deposition method or a sputtering method, and a configuration required for any of these methods may be used.

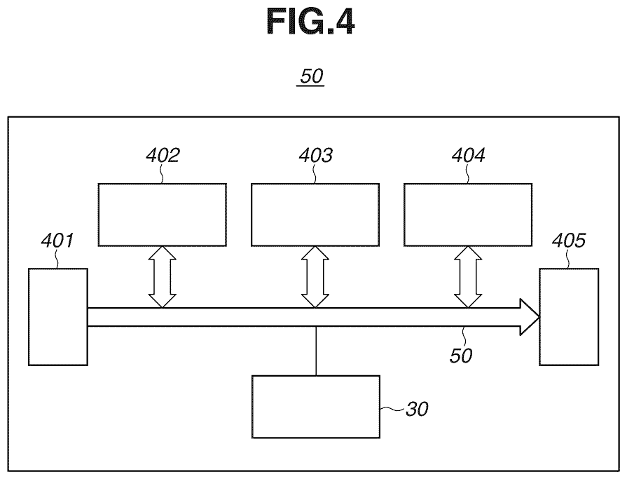

FIG. 4 illustrates a configuration in which the substrate 1 is conveyed inside the planarization apparatus 100 by the substrate conveyance unit 50. An arrow portion in FIG. 4 indicates the substrate conveyance unit 50 that is configured with a conveyance hand and the like. The substrate 1 carried in from a substrate carry-in unit 401 is conveyed to an adhesive layer processing unit 402 that includes the adhesive layer forming unit 40 in which the adhesive material is applied thereto. Then, the substrate 1 is conveyed to a planarization material application unit 403 that includes the supply unit 20 for supplying the composition PM, which is a planarization material, and the image acquisition unit 21 in which the planarization material is applied (supplied) thereto. The substrate 1 is then conveyed to a planarization processing unit 404 that includes the superstrate 11, the holding member 12 that holds the superstrate 11, the curing unit 24 that cures the planarization material and the like, is subjected to planarization processing, and is carried out from a substrate carry-out unit 405. The substrate conveyance processing is controlled by the control unit 30. FIG. 4 illustrates the configuration in which the adhesive layer processing unit 402, the planarization material application unit 403, and the planarization processing unit 404 are included in the same apparatus, but any of them may be included in a different apparatus.

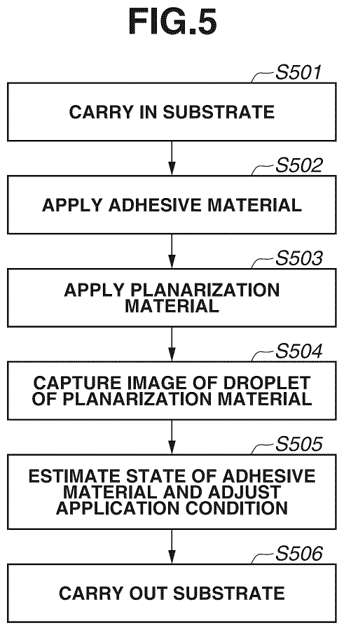

Next, a planarization method according to the present embodiment is described with reference to a flowchart of FIG. 5. Processing from step S501 to step S506 is described by extracting parts related to application of the adhesive material, application of the planarization material, image analysis of a droplet of the planarization material, and adjustment of a forming condition of the adhesive layer from the planarization processing by the planarization apparatus 100 according to the present disclosure.

First, in step S501, the substrate 1 is carried in from the substrate carry-in unit 401 by the substrate conveyance unit 50 in FIG. 4. Next, in step S502, the substrate 1 carried in is conveyed by the substrate conveyance unit 50 to the adhesive layer processing unit 402, and the adhesive layer forming unit 40 applies the adhesive material to the substrate 1. Next, in step S503, the substrate conveyance unit 50 conveys the substrate 1 to which the adhesive material is applied to the planarization material application unit 403 in which the supply unit 20 applies the planarization material (composition PM) to the substrate 1. Next, in step S504, the image acquisition unit 21 captures an image of droplet arrangement of the planarization material. Next, in step S505, a state of the adhesive material is estimated from the captured image of droplet arrangement, and the forming condition of the adhesive layer to be formed later is determined. In step S505, the image of droplet arrangement of the planarization material captured in step S504 is analyzed, the state of the adhesive material is estimated, a supply condition of the adhesive material is calculated, and the supply condition to be reflected in the next application is adjusted. Finally, in step S506, the substrate conveyance unit 50 carries out the substrate 1 from the substrate carry-out unit 405.

The processing in step S505 can be performed in several different methods. Two methods are described below.

First, a method is described in which an appropriate temperature in applying the adhesive material is estimated from a relationship between a temperature of the adhesive material and an abnormal droplet (abnormal residual liquid) that occurs between normal droplets of the planarization material, and the supply condition of the adhesive material is adjusted using the estimated result. In the following description, residual liquid of the planarization material in an abnormal state may sometimes be referred to as an “abnormal droplet”.

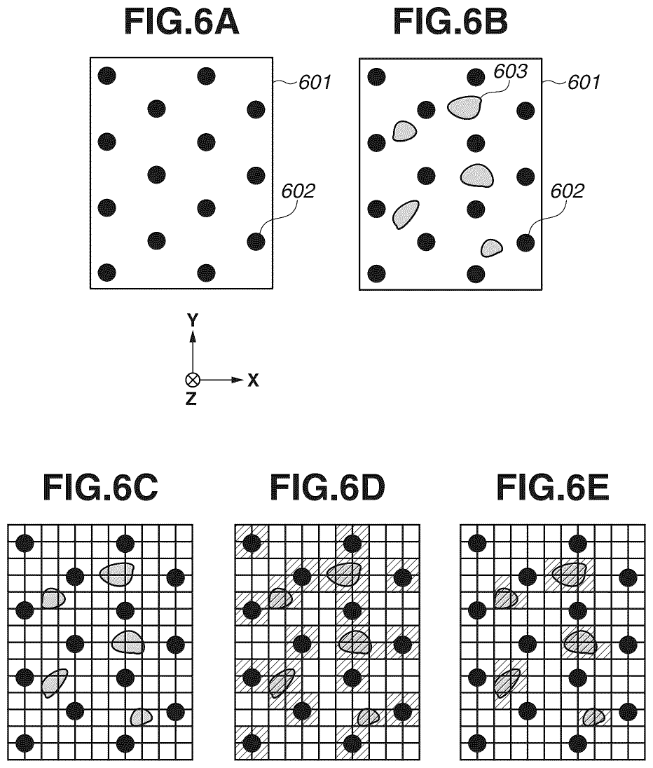

FIGS. 6A to 6E schematically illustrate images of droplets of the planarization material applied within a certain area on a substrate captured using the image acquisition unit 21 from the +Z-axis direction and illustrate a measurement area 601, a normal droplet 602, and an abnormal droplet 603. FIG. 6A illustrates droplets in a normal state in which each droplet is independent, and no abnormal droplet is observed in an area between adjacent droplets. FIG. 6B illustrates droplets in an abnormal state in which abnormal droplets remain in the areas between adjacent droplets. An abnormal droplet causes a phenomenon such as spreading more than a desired state because a state of the adhesive material is different from a desired state, resulting in exhibiting a mixture state where adjacent droplets are joined together and where they are not, and the like. In a case where the adhesive material is applied under an inappropriate temperature condition, the abnormal droplet tends to occur as illustrated in FIG. 6B, so that it is possible to estimate whether the adhesive material is applied appropriately by measuring the number of occurrences of the abnormal droplets.

Thus, according to the present embodiment, the state of the adhesive material is estimated by measuring the number of abnormal droplets within a certain area in a case where a temperature in applying the adhesive material is changed at regular intervals, and a condition that results in the smallest number of abnormal droplets is determined to be an optimal temperature condition and adjusted. In this case, the measurement area 601, which is a range in which the number of abnormal droplets is measured, may be a rectangular or circular area of a certain size or may be the entire substrate. A method for determining the optimal temperature condition may be a method for determining a temperature at which the number of abnormal droplets is a predetermined threshold value or less as the optimal condition in addition to the above-described method for determining a temperature at which the number of abnormal droplets is the smallest as the optimal condition. The threshold value may be, for example, a numerical value acquired from a theoretical calculation result or a numerical value empirically acquired from a result indicating that if the number of abnormal droplets is a certain number or less, there is no impact on other processes in the planarization process.

Next, a method for measuring the number of abnormal droplets is described. First, as illustrated in FIG. 6C, the measurement area 601 is divided into individual pixels. Each pixel is determined whether it contains a normal droplet, an abnormal droplet, or both using color information of red, green, and blue (RGB) or hue, saturation, and value (HSV). For example, a pixel containing a droplet can be extracted by detecting a pixel that includes the color information different from background color of the image. In this case, the pixel can be extracted more accurately by adding image processing such as noise removal as preprocessing. In FIG. 6D, results of detecting pixels containing droplets are illustrated by shaded areas. Next, the pixels containing droplets are classified into those of normal droplets and those of abnormal droplets. It is possible to identify the pixel in which the normal droplet is generated in the measurement area 601 based on position information and area information of the droplet acquired from the control unit 30. Thus, as illustrated in the shaded areas in FIG. 6E, the pixels of abnormal droplets are acquired by excluding the pixels of normal droplets from the pixels containing either normal or abnormal droplets, and an integrated value of the abnormal droplet pixels within the measurement area 601 becomes the number of abnormal droplets.

The state of the adhesive material is estimated using the number of abnormal droplets acquired as described above, and the optimal temperature condition is determined and adjusted.

Next, a second method is described in which a contact angle between the planarization material and the adhesive material is estimated, and the supply condition of the adhesive material is adjusted to acquire a contact angle within a desired range determined in advance. In the present method, a contact angle is estimated from a captured image as estimation of the state of the adhesive material in step S505.

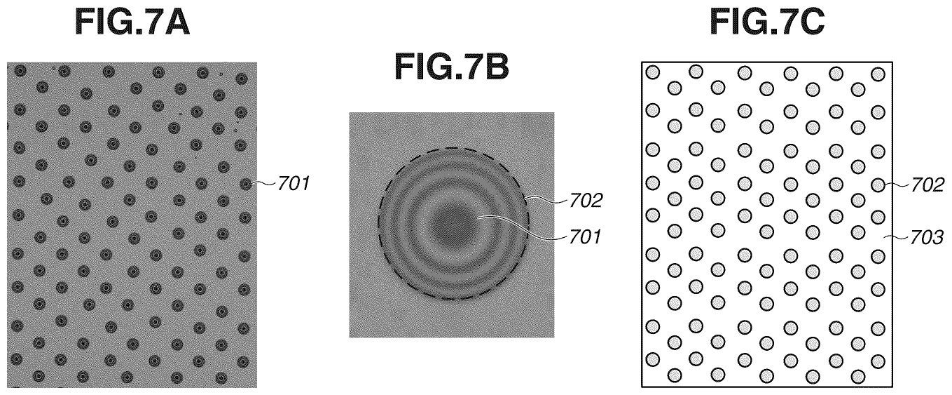

FIGS. 7A to 7C illustrate a method for extracting an area of each planarization material from a captured image.

In FIG. 7A illustrating a captured image, a planarization material 701 is arranged as individual droplets. In the captured image, the planarization material 701 may exhibit an interference pattern or other patterns. To extract an area of each planarization material from the captured image in FIG. 7A, a contour of the planarization material is extracted by image processing. FIG. 7B illustrates a state where a contour 702 of the droplet of the planarization material 701 is extracted by image analysis. An example of a method for extracting a contour includes a method for performing contour detection that detects a boundary of brightness in an image. As another example, there is a method for setting a threshold value of brightness in an image and determining an area darker than that of the threshold value as an area of the planarization material. FIG. 7C illustrates an image in which areas of the droplets containing the planarization material and the other areas are distinguished by image analysis. The areas, which are each enclosed by the contour 702, of droplets containing the planarization material are distinguished from other areas 703.

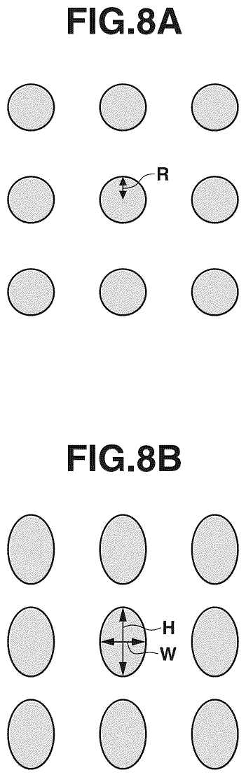

FIGS. 8A and 8B illustrate a method for measuring a size of an area of the droplet containing the planarization material. FIG. 8A illustrates a case where the droplet containing the planarization material has a circular shape. In the case of the circular shape, a radius R is acquired by acquiring the number of pixels within the circular area. FIG. 8B illustrates a case where the droplet containing the planarization material has an elliptical shape. In a case where the substrate has unevenness, the droplet containing the planarization material may have an elliptical shape as illustrated in FIG. 8B. In the case where the droplet has the elliptical shape, a vertical length H and a horizontal length W of the droplet can be acquired by acquiring the number of pixels forming the elliptical area.

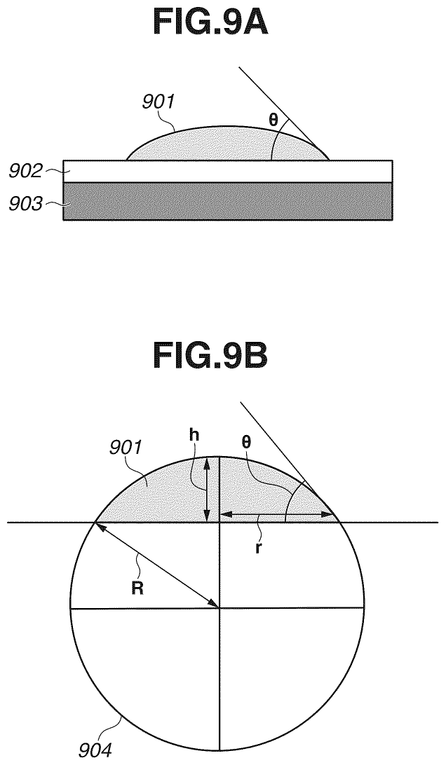

FIGS. 9A and 9B illustrate a method for calculating a contact angle between the adhesive material and the planarization material from a captured image. In FIG. 9A, a droplet 901 of the planarization material, an adhesive material 902, and a substrate 903 are illustrated. A contact angle θ between the adhesive material 902 and the planarization material is a calculation target. The contact angle θ can be calculated by considering the droplet 901 of the planarization material as a part of a sphere 904 as illustrated in FIG. 9B:

$$V = π h / 6 ( 3 r \hat{} 2 + h \hat{} 3 )$$

The above equation calculates a volume of a spherical cap, which can be used to calculate a volume of the droplet in a case where the droplet is considered as a part of the sphere 904. Here, h is a height of the droplet, r is a radius of the droplet being in contact with the adhesive material, and V is the volume of the droplet.

The contact angle θ can be expressed by the following equation:

$$r = R sin θ$$

Here, R is a radius of the sphere 904 that include the droplet as a part thereof.

A relationship between the radius r and the height h of the droplet can be expressed as follows:

$$r \hat{} 2 = 2 V / π h - 1 / 3 h \hat{} 2 ,$$

$$R \hat{} 2 = ( r \hat{} 2 + h \hat{} 2 ) / 2 h$$

The radius r of the droplet can be acquired by analyzing the captured image as described with reference to FIGS. 8A and 8B. The volume Vis information that is known in advance, and for example, it can be the volume of the droplet specified in a specification of the apparatus or an actual volume of the droplet measured by a measurement apparatus or the like. The contact angle θ can be calculated using the above-described equation. In this way, the contact angle θ is calculated as measurement information from the captured image in a process for analyzing a content of the captured image.

In the present method for adjusting the supply condition in step S505, the condition of the adhesive material is changed using the calculated contact angle θ.

In an example of changing the condition of the adhesive material, the condition of the adhesive material is changed so that the calculated contact angle θ approaches a desired contact angle θ.

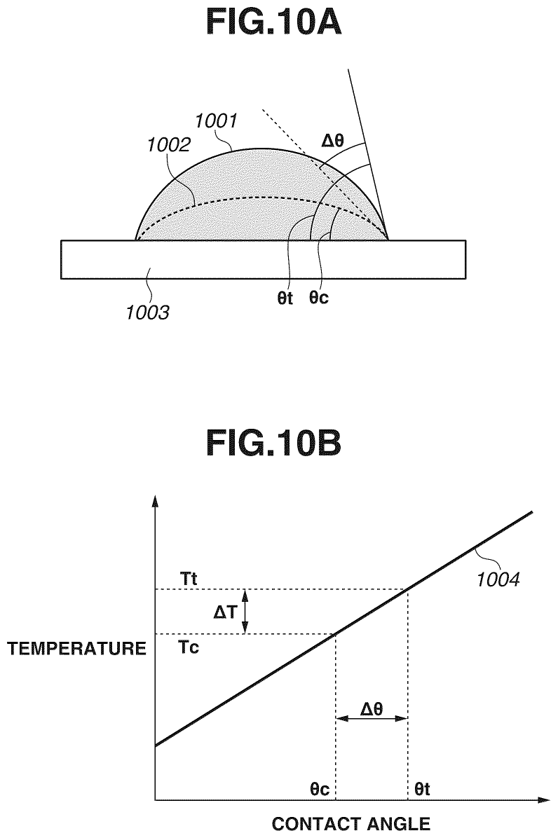

FIGS. 10A and 10B illustrate a method for changing the condition of the adhesive material from the calculated contact angle θ.

FIG. 10A illustrates a substrate 1003 and a droplet 1002 of the planarization material before changing the condition of the adhesive material. A contact angle of the droplet 1002 is denoted by Oc. In this example, the contact angle θc is small, and a larger contact angle θt is desired like a droplet 1001. Thus, the condition of the adhesive material is changed to achieve the target contact angle θt by increasing the contact angle by an amount 40, which is a difference from the current contact angle θc.

FIG. 10B illustrates a relationship between the supply condition of the adhesive material and the contact angle. Here, a temperature T, which is the supply condition of the adhesive material, is described as an example.

The relationship between the temperature T as the supply condition of the adhesive material and the contact angle θ can be expressed by the following equation:

$$T = f ( θ )$$

Here, f(θ) is an equation that expresses the relationship between the contact angle θ and the temperature T. This equation can be determined by measuring the contact angle θ while changing a value of the temperature T, which is the supply condition of the adhesive material.

A line 1004 in FIG. 10B represents f(θ). In FIG. 10B, the relationship between the contact angle θ and the temperature is expressed as linear as an example, but it may be nonlinear.

By using the relationship f(θ), it is possible to determine a temperature ΔT that can change the contact angle by Δθ. A temperature Tt, which is the supply condition of the adhesive material after the change, can be calculated as follows:

$$Tt = Tc + f ( θ t ) - f ( θ c )$$

In this way, in the present process, the supply condition of the adhesive material can be acquired using the contact angle θ acquired in the above-described process.

According to the above-described embodiment, the example is described in which an application temperature of the adhesive material is adjusted as the supply condition of the adhesive material. As the supply condition of the adhesive material, a change in an application time for changing an amount of an application material, narrowing an application area focusing on a location where abnormality occurs, and the like can be used. The relationship between the contact angle θ and the temperature T of the adhesive material illustrated in FIG. 10B can be changed depending on the adhesive material. Thus, the adhesive material can be a supply condition.

According to the above-described embodiment, a state of an adhesive material as an underlayer is estimated from a captured image of an applied planarization material, and a supply condition of the adhesive material is adjusted based on the estimated result, so that a high performance planarization apparatus can be provided.

### Second Embodiment

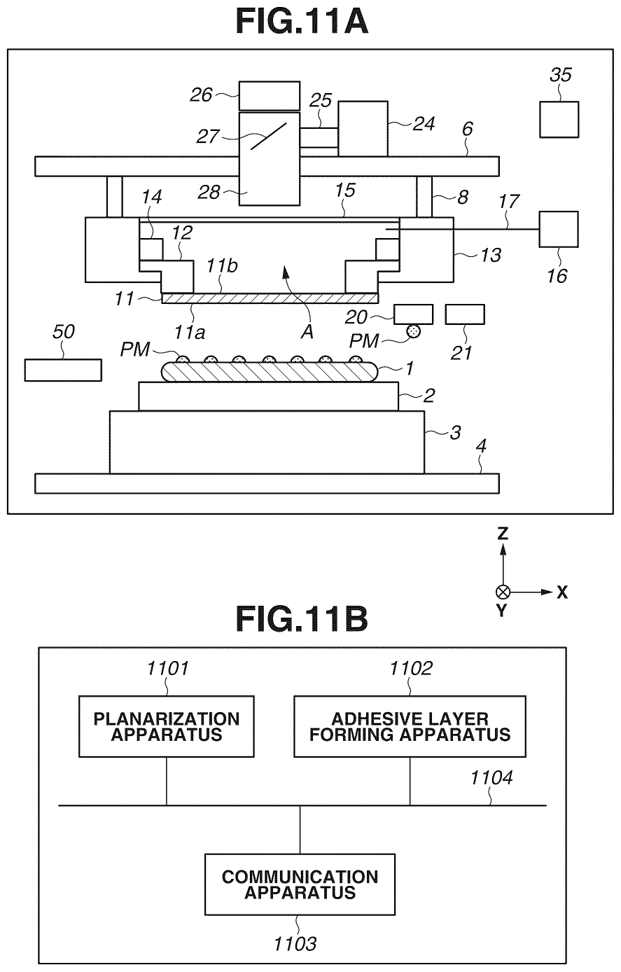

Next, a planarization apparatus and a method for estimating a state of an adhesive material and adjusting a supply condition according to a second embodiment are described with reference to FIGS. 11A and 11B. FIG. 11A illustrates the planarization apparatus according to the present embodiment. Unlike in FIG. 1, an adhesive layer forming unit is not included within the planarization apparatus. In other words, it is connected via a network 1104 and is arranged outside a frame of the planarization apparatus. Except that the adhesive layer forming unit is not included within the planarization apparatus, the configuration is similar to that in FIG. 1, and the reference numerals in FIG. 11A also indicate the same as those in FIG. 1. FIG. 11B illustrates a relationship between the planarization apparatus and an adhesive layer forming apparatus that performs adhesive layer forming processing according to the present embodiment. In the present configuration, an adhesive layer forming unit that is configured as the adhesive layer forming unit 40 within the planarization apparatus in FIG. 1 is configured as an adhesive layer forming apparatus 1102 outside a planarization apparatus 1101 and is connected to the network 1104 via an interface (not illustrated). At this time, a communication apparatus 1103 that enables communication between the planarization apparatus 1101 and the adhesive layer forming apparatus 1102 is also connected to the network 1104. The communication apparatus 1103 connects to, for example, the LAN and performs data communication using a communication protocol such as TCP/IP or the like.

The method for estimating the state of the adhesive material and adjusting the supply condition is executed in the processes illustrated in FIG. 5 as in the first embodiment. In this case, the adhesive material is applied to the substrate in the adhesive layer forming apparatus 1102, and then the substrate is conveyed to the planarization apparatus 1101. The state of the adhesive material is estimated from an image of the droplet arrangement of the planarization material in the planarization apparatus 1101 based on the method described in the first embodiment. After the supply condition of the adhesive material is determined, a set content of the new supply condition is transmitted from the planarization apparatus 1101 to the adhesive layer forming apparatus 1102 via the communication apparatus 1103, and the supply condition is updated and adjusted in the adhesive layer forming apparatus 1102.

### Other Embodiment

A molding apparatus is described above based on a planarization apparatus that performs planarization processing on a substrate, but the present disclosure is not limited to this, and can also be applied to an imprint apparatus that forms an uneven pattern on a surface of a mold and forms a pattern of a molding material (imprint material) on the substrate.

### (Method for Manufacturing Article)

A method for manufacturing an article includes forming a film of a curable composition on a substrate using the above-described molding method, processing the substrate on which the film of the curable composition is formed by the forming, and manufacturing an article from the substrate processed in the processing. A molding method is a pattern forming method or a planarization film forming method as described above.

A cured film having a pattern formed by the molding method according to the present disclosure is used as it is as a structural member for at least a part of various articles. A cured film having a pattern formed by the pattern forming method according to the present disclosure is temporarily used as a mask for etching or ion implantation performed on the substrate (a layer to be processed in a case where the substrate has a layer to be processed). The mask is removed after etching, ion implantation, or the like is performed in the processing process on the substrate. Accordingly, various articles can be manufactured.

In a case where a cured material is removed from a concave portion of a pattern on a cured material, a known method such as dry etching can be used without being specifically limited to a particular method. A known dry etching apparatus can be used for dry etching. A source gas for dry etching is appropriately selected according to an element composition of a cured material subjected to etching. Specifically, a halogen-based gas such as CF₄, C₂F₆, C₃F₈, CCl₂F₂, CCl₄, CBrF₃, BCl₃, PCl₃, SF₆, Cl₂, or the like can be used as the source gas. A gas containing oxygen atoms, such as O₂, CO, or CO₂, an inert gas such as He, N₂, or Ar, or a gas such as H₂ or NH₃ can also be used as the source gas. These gases can also be mixed and used as the source gas. In this case, to process an underlying substrate at a high yield, a photocured film is required to have high dry etching resistance.

Articles include an electrical circuit element, an optical element, a micro-electromechanical system (MEMS), a recording element, a sensor, a mold, or the like. Examples of the electrical circuit element include volatile or non-volatile semiconductor memories such as a dynamic RAM (DRAM), a static RAM (SRAM), a flash memory, and a magnetic RAM (MRAM), and semiconductor elements such as a large scale integrated (LSI) circuit, a charge coupled device (CCD), an image sensor, and a FPGA. Examples of the optical element include a microlens, a light guide body, a waveguide, an antireflection coating, a diffraction grating, a polarizing element, a color filter, a light-emitting element, a display, a solar cell, and the like. Examples of MEMS include a digital micromirror device (DMD), a microfluidic channel, an electromechanical conversion element, and the like. Examples of the recording element include optical disks such as a CD and a DVD, a magnetic disk, a magneto-optical disk, a magnetic head, and the like. Examples of the sensor include a magnetic sensor, an optical sensor, a gyroscope sensor, and the like. Examples of the mold include a mold for imprinting and the like.

A known photolithography process using an imprint lithography technique, an extreme ultraviolet (EUV) lithography technique, or the like can be performed on a planarization film formed using a planarization film forming method according to the present disclosure. Further, a spin-on glass (SOG) film and/or a silicon oxide layer can be laminated, and a curable composition can be applied thereon to perform the photolithography process. Accordingly, a device such as a semiconductor device or the like can be manufactured. It is also possible to form a device that includes the above-described device, such as an electronic device including a display, a camera, a medical device, or the like. Examples of the device include, for example, an LSI, a system LSI, a DRAM, a synchronous DRAM (SDRAM), a Rambus DRAM (RDRAM), a direct RDRAM (D-RDRAM), a NAND flash memory, and the like.

The present disclosure is not limited to the above-described embodiments, and various modifications and changes can be made without departing from the spirit and the scope of the present disclosure. The following claims are attached in order to publicize the scope of the present disclosure.

According to the present disclosure, for example, a new technique for molding a molding material can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-207052, filed Nov. 28, 2024, which is hereby incorporated by reference herein in its entirety.

What is claimed is:

1. A molding apparatus comprising:
an adhesive layer forming unit configured to form an adhesive layer on a substrate;
a supply unit configured to supply a droplet of a molding material to the substrate;
an image acquisition unit configured to acquire an image of the droplet of the molding material supplied on a specific substrate on which the adhesive layer is formed; and
a control unit configured to determine a forming condition for forming an adhesive layer on a substrate different from the specific substrate by the adhesive layer forming unit based on the image.

2. The molding apparatus according to claim 1, wherein the image is an image in which a plurality of the droplets is discretely arranged on the substrate on which the adhesive layer is formed.

3. The molding apparatus according to claim 2, wherein the forming condition of the adhesive layer includes a supply condition of an adhesive material that forms the adhesive layer.

4. The molding apparatus according to claim 3, wherein the supply condition of the adhesive material is at least one of an application temperature, an application time, an application area, or a composition of the adhesive material.

5. The molding apparatus according to claim 1, wherein information about an abnormal droplet in the image is acquired.

6. The molding apparatus according to claim 5, wherein the forming condition of the adhesive layer is determined so that a measured number of the abnormal droplets is a threshold value or less.

7. The molding apparatus according to claim 1, wherein information about a contact angle of the droplet of the molding material is acquired from the image.

8. The molding apparatus according to claim 1, wherein at least one piece of information about a position, an area, a spread shape, or a volume of the droplet of the molding material is acquired from the image.

9. The molding apparatus according to claim 8, wherein information about the position, the area, the spread shape, or the volume of the droplet of the molding material is acquired from the image.

10. The molding apparatus according to claim 1, wherein the forming condition of the adhesive layer is determined using a relationship between a contact angle of the droplet of the molding material and the forming condition of the adhesive layer.

11. The molding apparatus according to claim 1, wherein the molding material is a planarization material for planarizing a substrate, and wherein the molding apparatus is a planarization apparatus that planarizes the substrate.

12. The molding apparatus according to claim 1, further comprising:
a mold holding unit configured to hold a mold to be brought into contact with the molding material arranged on the substrate; and
a curing unit configured to cure the molding material in a state where the mold and the molding material are in contact.

13. The molding apparatus according to claim 1, wherein the adhesive layer forming unit is arranged external to a frame of the molding apparatus.

14. A method for molding, the method comprising:
forming an adhesive layer on a substrate;
supplying a droplet of a molding material to the substrate;
acquiring an image of the droplet of the molding material supplied on a specific substrate on which the adhesive layer is formed; and
determining a forming condition for forming an adhesive layer on a substrate different from the specific substrate based on the image.

15. The method according to claim 14, further comprising acquiring a relationship between a state of a droplet arranged on the substrate and a state of the adhesive layer.

16. The method according to claim 14, wherein the forming condition of the adhesive layer is determined using a relationship between a contact angle of the droplet of the molding material and the forming condition of the adhesive layer.

17. A method for manufacturing an article, the method comprising:
molding a substrate using the method for molding according to claim 14;
processing the substrate subjected to the molding; and
acquiring an article from the substrate subjected to the processing.

18. A method for manufacturing an article, the method comprising:
molding a substrate using a forming condition determined by the molding apparatus according to claim 1;
processing the substrate subjected to the molding; and
acquiring an article from the substrate subjected to the processing.
